(19) United States
(12) Patent Application Publication
(10) Pub. No.: US 2022/0139782 A1
(43) Pub. Date: May 5, 2022

(54) METHOD FOR MANUFACTURING MOS TRANSISTORS COMPRISING DIELECTRIC SPACERS AND CORRESPONDING INTEGRATED CIRCUIT

(71) Applicant: STMicroelectronics (Rousset) SAS, Rousset (FR)

(72) Inventor: Franck JULIEN, La Penne sur Huveaune (FR)

(73) Assignee: STMicroelectronics (Rousset) SAS, Rousset (FR)

(21) Appl. No.: 17/516,857

(22) Filed: Nov. 2, 2021

(30) Foreign Application Priority Data
Nov. 3, 2020 (FR) 2011281

(51) Int. Cl. H01L 21/8234; H01L 21/306; H01L 21/266; H01L 21/308; H01L 29/66

(52) U.S. Cl. CPC H01L 21/823468; H01L 21/30608; H01L 29/6656; H01L 21/3081; H01L 21/266

(57) ABSTRACT

An integrated circuit includes metal-oxide-semiconductor “MOS” transistors formed on a semiconductor substrate. The MOS transistors have gate stacks belonging to at least one gate stack category and dielectric regions of sidewall spacers on the sides of the gate stacks. At least a first MOS transistor has a gate stack of said at least one gate stack category that includes dielectric regions of sidewall spacers having a first width. At least a second MOS transistor has a gate stack of the same gate stack category with dielectric regions of sidewall spacers having a second width different from the first width.

### PRIORITY CLAIM

This application claims the priority benefit of French Application for Patent No. 2011281, filed on Nov. 3, 2020, the content of which is hereby incorporated by reference in its entirety to the maximum extent allowable by law.

### TECHNICAL FIELD

Embodiments and implementations relate to microelectronics, in particular the manufacture of integrated circuits comprising Metal Oxide Semiconductor (MOS) type transistors having dielectric regions of sidewall spacers.

### BACKGROUND

The dielectric regions of sidewall spacers (usually “spacers”) are typically formed on the sides of the MOS transistor gate stacks. The sidewall spacers allow on the one hand to move the contacts of the conduction regions of the transistor (source and drain) away from the gate region, and on the other hand to be used as a self-aligned mask for the implantation of the conduction regions.

The positioning of the conduction regions defines the length of the channel region of the transistor and consequently the morphology of the sidewall spacers can allow to define the effective size of the gate length (that is to say also, but more rarely used, the length of the channel region). Thus, the morphology of the sidewall spacers has an impact on short channel effects, on performance (in particular the residual current in the turned-off state “Ioff”, the drain current at saturation, the resistance in the turned-on state) and the reliability of the transistor (in particular ageing and phenomena of degradation by hot carriers).

Nevertheless, in conventional manufacturing methods the formation of the sidewall spacers is often inflexible and highly dependent on the formation of a particular type of gate stack.

However, more and more different transistors are required in multifunctional applications, the voltage ranges are increasingly large and the costs must be low.

Consequently, several transistors of the same type, called “family” of transistors, can be configured to have, in particular, different threshold voltages for different functions, but conventionally all include sidewall spacers of a single morphology. Indeed, the sidewall spacers are typically manufactured in a method for manufacturing gate stacks that is global and common to all the transistors of the same family.

Consequently, the unique morphology of the sidewall spacers may be unsuitable or disadvantageous for some functions of the different transistors of the same family.

Adding dedicated steps of specific spacer formation for some transistors typically introduces thermal budget and dry etches in plasma environment, which is expensive and can cause damage to surrounding structures.

The formation of sidewall spacers of the same family is conventionally provided to have the minimum width tolerated in all the functions of the different transistors of the same family, that is to say the largest tolerated minimum width of the family. Consequently, some transistors which may have finer sidewall spacers are conventionally not optimized, in particular in terms of space requirement.

Thus, there is a need to manufacture sidewall spacers of different morphologies for transistors of the same family economically and without affecting the surrounding structures (that is to say in particular without additional thermal budget or plasma etching), in particular in order to improve the performance of devices on existing technologies and to benefit from additional degrees of freedom in the design of integrated circuits.

### SUMMARY

In an embodiment, a method for manufacturing transistors of the metal-oxide-semiconductor “MOS” type on an integrated circuit semiconductor substrate, comprises: manufacturing gate stacks of at least one gate stack category; forming a conformal layer of a dielectric spacer material of constant thickness on the gate stacks of said at least one gate stack category; isotropic etching to reduce without completely removing a thickness of the dielectric spacer material selectively in a first area opposite at least a first gate stack of said at least one gate stack category, and not in a second area opposite at least a second gate stack of said gate stack category; and anisotropic etching to completely remove the thickness of the dielectric spacer material on top of said gate stacks and on the substrate while leaving a remainder of the thickness of dielectric spacer material laterally on the sides of said gate stacks of said at least one gate stack category in both the first area and the second area.

A “gate stack category” is understood, in particular, to comprise gate stacks which all include structurally identical dielectric gate layers, and structurally identical conductive gate layers. And, “structurally identical” means, in particular, at least the same nature or composition of material(s), and the same thickness.

Since the thickness of the dielectric spacer material is thinner in the first area than in the second area, the remainder remaining on the sides of said gate stacks is also thinner in the first area than in the second area.

In other words, the method allows to produce sidewall spacers having different thicknesses for gate stacks of the same category, in a selective and non-global manner, but with a single step of depositing the dielectric spacer material, and a single anisotropic etching step.

It will be noted that the step of depositing the dielectric spacer material does not require additional heat treatment, and therefore this step of the method does not introduce any risk of disturbance of neighboring devices of the integrated circuit.

It will also be noted that the isotropic etching step is carried out without plasma treatment, given that this isotopic etching does not completely remove the thickness of the dielectric spacer material, and consequently this step of the method does not introduce the risk of disturbance of neighboring devices of the integrated circuit.

Consequently, the method can economically fit into an existing method and does not introduce a risk of damaging neighboring structures.

It is thus possible to manufacture transistors with specific spacers (or none), for example in order to improve the performance and to reduce the size of the transistors, in an approach compatible and adaptable to the conventional methods for manufacturing transistors having gate stacks belonging to the same category, and without impact on the other elements of the integrated circuit.

According to one implementation, the manufacture of each gate stack category comprises a set of common steps comprising forming a dielectric gate layer on the semiconductor substrate and forming a conductive gate layer on the dielectric gate layer.

According to one implementation, the method further comprises a step of forming conduction regions of the transistors comprising an implantation of dopants in the substrate which is self-aligned on an outer edge of remainders of the thickness of the dielectric spacer material remaining on the sides of the gate stacks of said at least one category.

The conduction regions of the transistors, that is to say the source region and the drain region, may include low doped pockets, usually called “lightly doped drain regions” (on the side of the drain region and on the side of the source region) or “LDD” for “Lightly Doped Drain”. The term “self-aligned” usually means that the sidewall spacers define the implanted regions, much like a mask.

Consequently, the implanted regions of the transistors of the first area are laterally closer than in the transistors of the second area, and thus the features (such as the residual current in the turned-off state, the saturation drain current or the resistor in the turned-on state) of the transistors having a gate stack of the same category can be optimized for a given function in the first area, and for another function in the second area.

According to one implementation, the isotropic etching step comprises a wet etching with a chemical species adapted for etching the dielectric spacer material, and, prior to the wet etching, a treatment of the dielectric spacer material modifying the rate of etching the dielectric spacer material by said chemical species, selectively in the first area and/or in the second area, so that the rate of etching the dielectric spacer material by said chemical species is greater in the first area than in the second area.

Thus, the treatment is configured to either increase the rate of etching the dielectric spacer material in the first area, or decrease the rate of etching the dielectric spacer material in the second area, or both increase the rate of etching the dielectric spacer material in the first area and decrease the rate of etching the dielectric spacer material in the second area.

In this regard, the treatment can in all cases comprise the use of a photolithography mask exposing the first area to increase the etching rate in the first area, and/or protecting the second area to decrease the etching rate in the second area.

According to one implementation, said treatment comprises a use of a temporary mask uncovering the first area and covering the second area, and an ion implantation adapted to damage the dielectric spacer material in the first area so as to increase the rate of etching the dielectric spacer material by said chemical species in the first area.

Indeed, the use of a temporary mask, for example made of photolithography resin, allows to act selectively in the first area to increase the etching rate of the dielectric spacer material.

According to one implementation, the energy of the implantation is configured according to the choice of the dopant ion species, for example phosphorus or argon, and according to the thickness of the dielectric spacer material and of the desired reduction in said thickness during the isotropic etching step.

It is indeed possible to quadruple the rate of etching the implanted dielectric spacer material, over a thickness parameterized by the energy of the implantation.

According to one implementation, said treatment comprises the use of a hard mask uncovering the first area and covering the second area, the material of the hard mask being adapted to withstand said wet etching so as to reduce the etching rate, or even prevent the etching, of the dielectric spacer material by said chemical species in the second area.

For example, the formation of the hard mask comprises a deposition of a layer of hard mask material, on the thickness of the dielectric spacer material, then a use of a temporary mask, for example made of photolithography resin, exposing the hard mask material in the first area, and a selective etching of the hard mask material without degrading the dielectric spacer material in the first area.

The use of the hard mask covering the second area allows to act selectively in the second area to decrease the etching rate of the dielectric spacer material.

According to one implementation, after said isotropic etching step, the hard mask is selectively wet-removed by a chemical species adapted for dissolving the material of the hard mask without degrading the dielectric spacer material.

According to one implementation, said at least one gate stack category comprises: a category of low voltage gate stacks intended to operate at gate voltages less than 2 volts; and/or a category of medium voltage gate stacks intended to operate at gate voltages comprised between 1.5 volts and 5 volts; and/or a category of high voltage gate stacks intended to operate at gate voltages comprised between 5 volts and 15 volts; and/or a category of memory cell gate stacks including a superposition of a control gate stack on a floating gate stack.

According to another aspect, provision is made of an integrated circuit including transistors of the metal-oxide-semiconductor “MOS” type disposed on a semiconductor substrate, having gate stacks belonging to at least one gate stack category and dielectric regions of sidewall spacers on the sides of the gate stacks, wherein at least a first transistor having a gate stack of said at least one gate stack category includes dielectric regions of sidewall spacers having a first width, and at least a second transistor having a gate stack of the same gate stack category includes dielectric regions of sidewall spacers having a second width different from the first width.

According to one embodiment, the gate stacks comprise a dielectric gate layer on the semiconductor substrate and a conductive gate layer on the dielectric gate layer, the gate stacks belonging to a same gate stack category including structurally identical dielectric gate layers and structurally identical conductive gate layers.

According to one embodiment, the MOS transistors comprise conduction regions aligned on an outer edge of the width of the dielectric regions of sidewall spacers.

According to one embodiment, said at least one gate stack category comprises: a category of low voltage gate stacks intended to operate at gate voltages less than 2 volts; and/or a category of medium voltage gate stacks intended to operate at gate voltages comprised between 1.5 volts and 5 volts; and/or a category of high voltage gate stacks intended to operate at gate voltages comprised between 5 volts and 15 volts; and/or a category of memory cell gate stacks including a superposition of a control gate stack on a floating gate stack.

### BRIEF DESCRIPTION OF THE DRAWINGS

Other advantages and features of the invention will become apparent upon examining the detailed description of the embodiment and implementation, which are in no way limiting, and of the appended drawings wherein:

FIGS. 1-3 illustrate the results of steps of a method of manufacture;

FIGS. 4-5 illustrate a method for isotropic etching;

FIGS. 6-8 illustrate another method for isotropic etching; and

FIG. 9 illustrates an integrated circuit obtained by the method described in relation to FIGS. 1-8.

### DETAILED DESCRIPTION

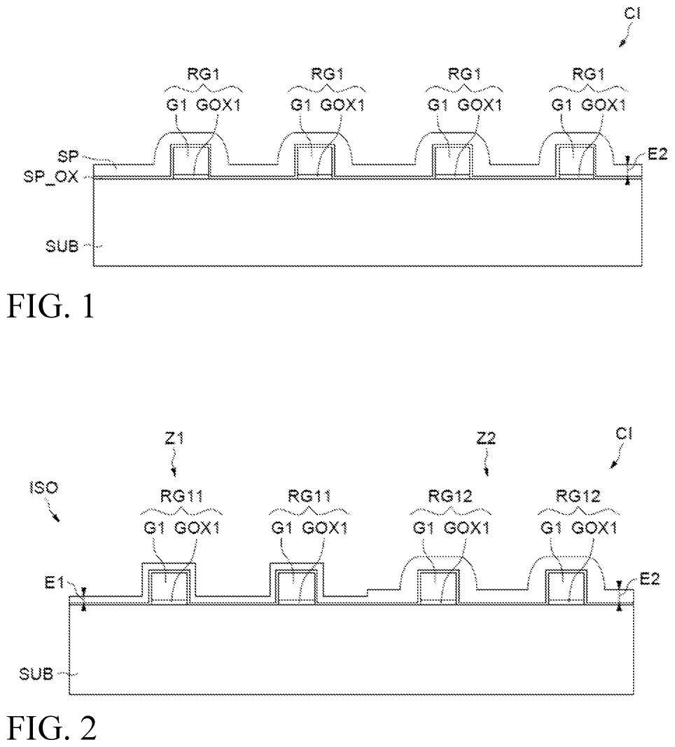

FIG. 1 illustrates the result of a step of manufacturing transistors T11, T12 (FIG. 3) of the metal-oxide-semiconductor “MOS” type on a semiconductor substrate SUB of an integrated circuit CI.

More particularly, FIG. 1 illustrates a preliminary stage of forming sidewall spacers with a dielectric spacer material SP.

At this stage of manufacture, gate stacks RG1 of the transistors have been manufactured on the semiconductor substrate SUB.

The gate stacks RG1 each comprise a dielectric gate layer GOX1, typically made of silicon dioxide and located on a face called the front face of the substrate SUB, and a conductive gate layer G1, typically made of polycrystalline silicon and located on the dielectric gate layer GOX1.

The gate stacks RG1 whose dielectric gate layers GOX1 are structurally identical and whose conductive gate layers G1 are structurally identical constitute the same gate stack category. “Structurally identical” means at least the same nature or composition of material(s), and the same thickness.

In fact, the manufacture of the gate stacks RG1 belonging to the same gate stack category comprises a common step of forming a dielectric gate layer GOX1 on the semiconductor substrate SUB, and a common step of forming a conductive gate layer G1 on the dielectric gate layer GOX1.

An anisotropic etching through the pattern of a photolithography mask then allows to delimit the unitary gate stacks RG1 in the superposition of the dielectric gate layer GOX1 and the conductive gate layer G1.

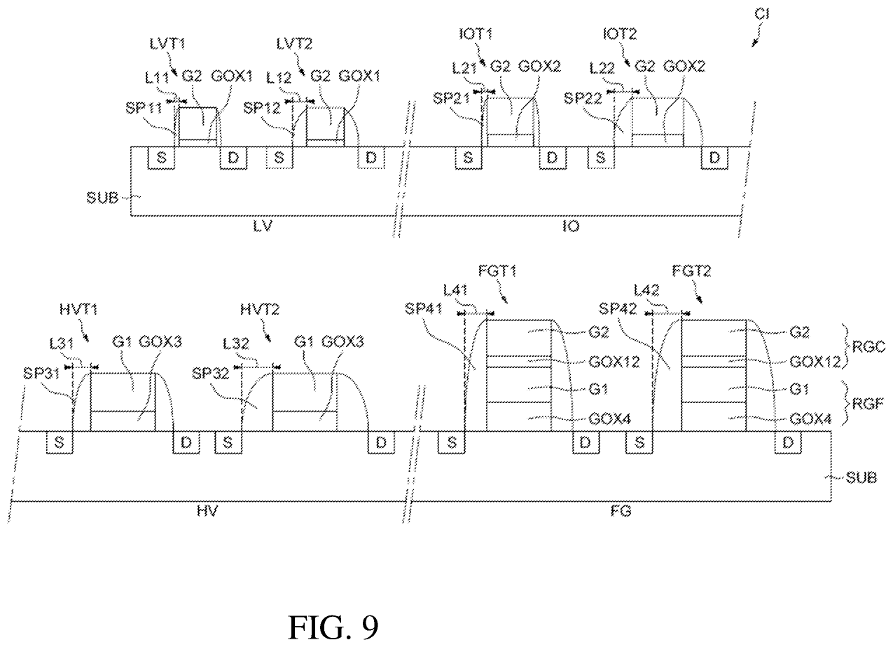

In FIG. 1, only one gate stack RG1 category is shown, however, at least one other gate stack category may have been formed on the substrate SUB at this stage. Furthermore, the formations of gate stacks of different categories may comprise a common step among forming the dielectric gate layer or forming the conductive gate layer. For example, two gate stacks of different categories may result from two distinct steps of forming the dielectric gate layer GOX1, GOX2 (FIG. 9) and from a common step of forming the conductive gate layer G1 (FIG. 9).

To form sidewall spacers on the sides of the gate stacks RG1 belonging to said at least one gate stack category, a conformal layer of constant thickness E2 of a dielectric spacer material SP is formed on the gate stacks RG1 and the substrate SUB.

The constant thickness E2 has the same size E2 in all directions of the surface on which it rests (that is to say the same thickness E2 on the horizontal portions and on the vertical portions of the surface on which it rests), can be obtained by a conformal deposition of the Chemical Vapor Deposition “CVD” type or of the Physical Vapor Deposition “PVD” type.

The dielectric spacer material SP is typically silicon nitride.

Furthermore, a dielectric layer SP_OX underlying the thickness of the dielectric spacer material SP, is advantageously formed from another dielectric material SP_OX, typically silicon oxide, prior to the formation of the dielectric spacer material SP. The dielectric layer SP_OX can, for example, be produced by deposition or by oxidation such as a re-oxidation of the gates and of the substrate. The underlying dielectric layer SP_OX will allow to control the anisotropic etching described below in relation to FIG. 3, and to protect the substrate SUB and the gate stacks RG1 against said anisotropic etching.

In a conventional method, the anisotropic etching step is performed on the structure of FIG. 1, and results in the formation of conventional sidewall spacers having the same thickness on the sides of all the gate stacks of said at least one category.

FIG. 2 illustrates the result of an additional step allowing to form, in a simple and economical manner, sidewall spacers having different widths.

An isotropic etching step ISO is implemented on the structure of FIG. 1 in order to reduce the thickness E2 of the dielectric spacer material SP, without completely removing said thickness E2, thus resulting in a non-zero thickness E1 less than the initial thickness E2.

The reduction in thickness is done selectively in a first area Z1 of the integrated circuit CI, and not in a second area Z2 of the integrated circuit CI. The first area Z1 is located opposite at least a first gate stack RG11 of said at least one category, and the second area Z2 is located opposite at least a second gate stack RG12 of the same category.

To implement the isotropic etching ISO with selectivity between the first area Z1 and the second area Z2, the isotropic etching step ISO first comprises a selective treatment of the dielectric spacer material SP. The treatment comprises a use of a photolithography mask exposing the dielectric spacer material SP in the first area Z1 to increase the etching rate therein in reaction to an isotropic etching chemical species. Additionally or alternatively, the photolithography mask is used to protect the dielectric spacer material SP in the second area Z2 to decrease its etching rate therein in reaction to said isotropic etching chemical species.

Thus, the treatment is configured either to increase the rate of etching the dielectric spacer material SP in the first area Z1, or to decrease the rate of etching the dielectric spacer material SP in the second area Z2, or to both increase the rate of etching the dielectric spacer material SP in the first area Z1 and decrease the rate of etching the dielectric spacer material SP in the second area Z2.

The isotropic etching step ISO then comprises a phase of wet etching by the chemical species, adapted for etching (that is to say “dissolving” for a wet etching) the dielectric spacer material SP, such as, for example, phosphoric acid H₃PO₄ heated between 100° C. and 200° C., in the case of silicon nitride.

As a result of the treatment described above, the reaction rate of the dielectric spacer material SP with said chemical species is greater in the first area Z1 than in the second area Z2. In the case where the dielectric spacer material SP is protected in the second area Z2, it can be considered that the reaction rate of the dielectric spacer material SP is reduced to the point of being zero in the second area Z2.

Thus, the wet etching dissolves a greater amount of the dielectric spacer material SP in the first area Z1 than in the second area Z2. The exposure time to the etching chemical species is controlled so as not to completely remove the thickness of the dielectric spacer material SP in the first area Z1.

After the isotropic etching step ISO, the dielectric spacer material SP layer has a thickness E1 which is thinner in the first area Z1 than the thickness E2 in the second area Z2.

It will be noted that since the wet etching is configured so as to not completely remove the thickness of dielectric material in the first area Z1, the underlying structures and the substrate are not at risk of being damaged by the wet etching. For example, the time of exposure to the wet etching chemical species can be adjusted in order to ensure that the dielectric material thickness SP is not completely removed.

Furthermore, the dielectric layer SP_OX located below the thickness of the dielectric spacer material SP can be selected to withstand wet etching, to protect the underlying structures and the substrate. This is particularly the case when the dielectric layer SP_OX is formed from silicon dioxide and the wet etching uses phosphoric acid which has a very high selectivity on the spacer dielectric made of silicon nitride relative to silicon dioxide.

FIG. 3 illustrates the result of an anisotropic etching ANISO carried out on the structure of FIG. 2, allowing to form the sidewall dielectric spacers on the sides of the gate stacks RG11, RG12 of the transistors T11, T12, as well as of an ionic implantation II of the conduction regions of the transistors.

The anisotropic etching ANISO, typically a dry etching in a plasma environment such as a Reactive Ion Etching “ME”, is directed perpendicular to the front face of the substrate SUB, so as to completely remove the thicknesses E1, E2 of the dielectric spacer material SP on the substrate SUB and on top of said gate stacks RG1, while leaving a remainder L1, L2 of the thickness of the dielectric spacer material SP laterally on the sides of said gate stacks RG11, RG12 of said at least one category. The anisotropic etching is carried out simultaneously in the first area Z1 and in the second area Z2. Advantageously, the anisotropic etching ANISO is configured so as not to cross the dielectric layer SP_OX underlying the spacer dielectric thickness SP, in a use called “screen oxide” use, so as not to touch the substrate SUB.

Since the thickness of the dielectric spacer material SP was thinner on the sides of the gates RG11 of the first transistors T11 located in the first area Z1 than on the sides of the gates RG12 of the second transistors T12 located in the second area Z2, the width L1 of the remainder of the thickness of the dielectric spacer material SP in the first area Z1 is smaller than the width L2 of the remainder of the thickness of the dielectric spacer material SP in the second area Z2.

The remainders of the thicknesses of the dielectric spacer material SP remaining on the sides of the gate stacks thus formed constitute the dielectric regions of the sidewall spacers, usually referred to as “spacers”.

Note that the dielectric regions of the sidewall spacers are substantially semi-parabolic in shape, thus the width of a dielectric region of a sidewall spacer is not constant along the height of the spacer. In FIGS. 3 and 9, the widths shown are taken at the base of the spacers, that is to say the widest part located at the substrate. Nevertheless, another measurement point can also be taken, such as usually the width at mid-height of the spacers. Also, a vertical recess parameter defined by the height difference between the highest point of the spacer and the top of the gate stack (not shown), depends on the width of the spacer, and can allow to characterize said widths of the spacers.

Thus, when the distinct widths (L1, L2) of the dielectric regions of sidewall spacers are mentioned, the widths taken at the same measuring point, such as at the base and at mid-height, will be considered, as well as, optionally, the sizes of the vertical recesses.

Consequently, the integrated circuit CI includes MOS-type transistors T11, T12 having gate stacks RG11, RG12 belonging to the same gate stack category, and having dielectric regions of sidewall spacers SP on the sides of the gate stacks RG11, RG12, of different widths L1, L2.

After forming the dielectric regions of sidewall spacers SP1, SP2, the step II of implanting dopants in the substrate SUB is performed in a self-aligned manner on the outer edges of the dielectric regions of sidewall spacers SP1, SP2. The dopants thus implanted form conduction regions of the transistors T11, T12, such as the source and drain regions, or Lightly Doped Drain “LDD” regions.

The spacers SP1, SP2 of different widths L1, L2 thus allow, in particular, to modulate the features, such as the residual current in the turned-off state, the drain current at saturation or the resistance in the turned-on state, of the transistors T11, T12 yet having a gate stack of the same category.

Furthermore, the size of the first transistors T11 thus obtained is smaller than the second transistors T12.

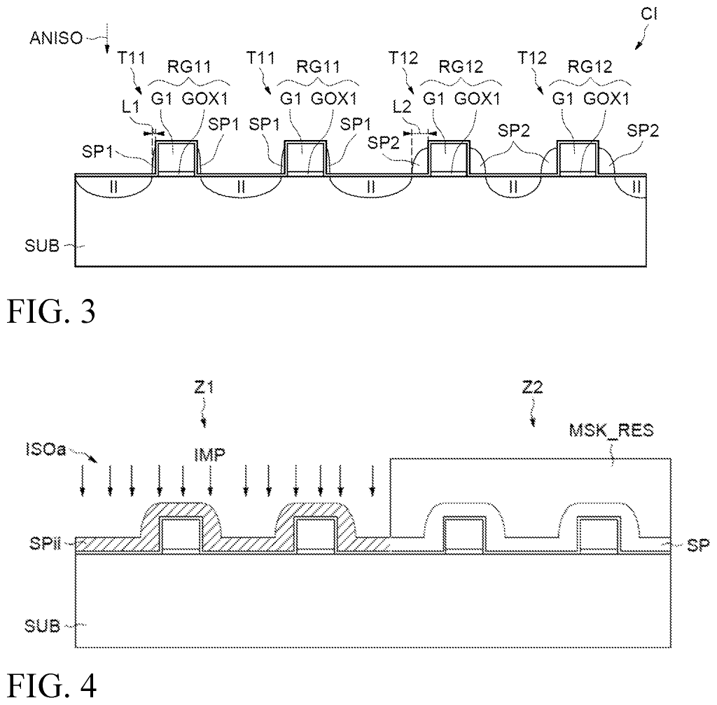

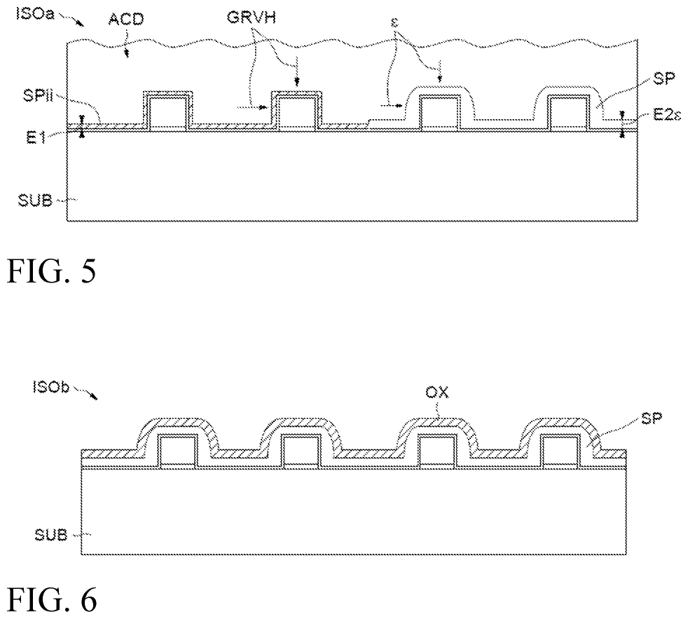

FIGS. 4 and 5 illustrate steps of a first example ISOa of the isotropic etching step ISO, this step including the selective treatment of the thickness of the dielectric spacer material.

FIGS. 6 to 8 illustrate steps or results of steps of a second example ISOb of the isotropic etching step ISO, this step including the selective treatment of the thickness of the dielectric spacer material SP, which can be taken alternatively or in combination with the first example.

FIG. 4 illustrates a first treatment of the dielectric spacer material SP selectively modifying the reaction rate of the dielectric material SP so that the reaction rate of the dielectric spacer material SP with the chemical species ACD (FIG. 5) is greater in the first area Z1 than in the second area Z2.

The treatment comprises a use of a temporary mask MSK_RES, typically made of photolithography resin, uncovering the first area Z1 and covering the second area Z2, and an ion implantation IMP in the uncovered portions of the dielectric spacer material SP.

The ion implantation IMP is adapted to damage the dielectric spacer material SPii so as to increase the reaction speed of the dielectric spacer material SPii with the chemical species ACD (FIG. 5) in the part which is not covered by the temporary mask MSK_RES, that is to say in the first area Z1.

The energy of the implantation IMP is configured according to the choice of the ionic species, for example phosphorus or argon, and according to the initial thickness E2 of the dielectric spacer material SP and the reduced thickness E1 desired at the end of the isotropic wet etching GRVH (FIG. 5).

The greater the implantation energy, the deeper the ions penetrate into the thickness of the dielectric spacer material SPii, and the deeper the etch will be. The increase in the etching rate indeed results from the presence of implanted particles, thus, the etching rate differential will be present for a greater thickness in the first area Z1.

For example, an implantation of phosphorus in silicon nitride at a surface density of 10¹⁵ atoms/cm² and an energy of 20 keV to 40 keV allows to substantially multiply by 4 the etching rate over a thickness of the order of 10 nm to 20 nm. The same results can be achieved with an implantation of argon at the same concentration and an energy comprised between 1 keV and 100 keV.

FIG. 5 illustrates the wet etching step.

The wet etching GRVH comprises placing the entire integrated circuit IC in a bath of an etching chemical species ACD, typically phosphoric acid at high temperature (between 100° C. and 200° C.) if the dielectric material of the spacer is made of silicon nitride.

The etching chemical species ACD rapidly dissolves GRVH the ion implanted dielectric spacer material SPii in the first area Z1. The etching chemical species ACD also reacts with the dielectric spacer material SP in the second area Z2, but with a kinetics considered negligible compared to the rate of etching GRVH in the first area Z1.

Thus, the thickness E2ε of the dielectric spacer material SP in the second area Z2 is reduced slightly but in a negligible manner compared to the reduction in the thickness of the dielectric spacer material SPii in the first area Z1. The initial thickness E2 of the spacer dielectric can be provided to compensate for said decrease (c) in the thickness E2ε in the second area Z2.

The structure illustrated by FIG. 2 is thus obtained and the steps described in relation to FIG. 3 can be carried out to obtain the transistors T11, T12 having dielectric regions of sidewall spacers of different widths L1, L2.

FIG. 6 illustrates a step of forming a layer of a hard mask material OX, on the dielectric thickness of the spacer SP illustrated in FIG. 1. The material OX of the hard mask MSK_OX is adapted to withstand said wet etching GRVH (FIG. 8) of the isotropic etching step ISOb. In the case where the dielectric spacer material SP is made of silicon nitride, the hard mask material OX can advantageously be silicon dioxide.

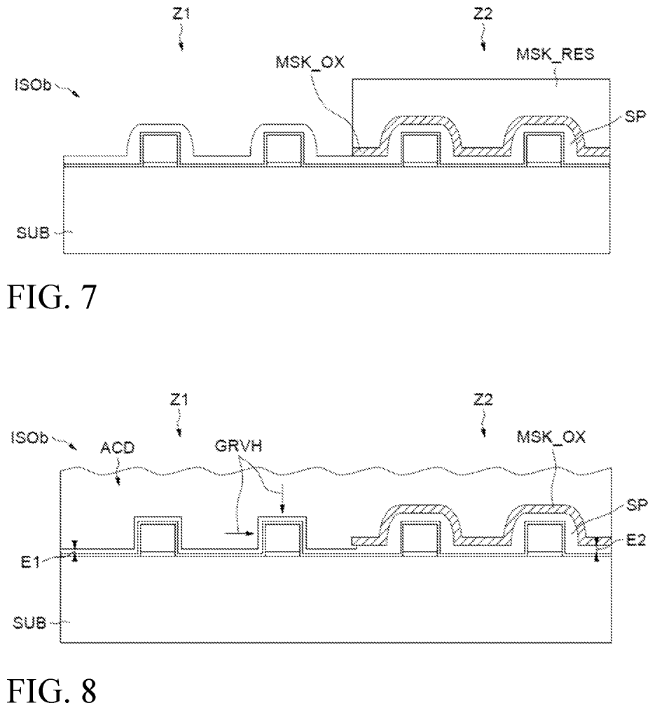

FIG. 7 illustrates a formation of a hard mask MSK_OX using a temporary photolithography resin mask MSK_RES covering the second area Z2, in order to selectively remove the hard mask material OX in the first area Z1.

For example, the removal of the hard mask material OX in the first area Z1 can be obtained by means of wet etching with a chemical species selectively attacking the hard mask material OX but not the photolithography resin, such as a dilute or buffered hydrofluoric acid solution (usually “BOE” for “Buffered Oxide Etch”) in the case of the silicon oxide.

Thus, the treatment comprises forming a hard mask MSK_OX uncovering the first area Z1 and covering the second area Z2.

FIG. 8 illustrates the wet etching step identical to the wet etching described above in relation to FIG. 5.

But in this case, given that the material OX of the hard mask MSK_OX is adapted to withstand said wet etching GRVH, the wet etching GRVH is not accelerated in the first area Z1 but is slowed down in the second area Z2.

Thus, in the second area Z2, the rate of etching the dielectric spacer material SP with said chemical species ACD is reduced to the point of being completely inhibited, with the exception of the parts located below the borders of the hard mask MSK_OX.

After the wet etching GRVH of FIG. 8, the hard mask MSK_OX is selectively wet-removed from the chemical species adapted to dissolve the hard mask material OX without degrading the dielectric spacer material SP, for example the hydrofluoric acid chemical species used in the step described in relation to FIG. 7.

The structure illustrated by FIG. 2 is thus obtained and the steps described in relation to FIG. 3 can be carried out to obtain the transistors T11, T12 having dielectric regions of sidewall spacers of different widths L1, L2.

In summary, the treatment of the isotropic etching step ISOa, ISOb is configured either to increase the rate of etching the dielectric spacer material SP in the first area Z1 (according to the example of FIG. 4), or to decrease the rate of etching the dielectric spacer material SP in the second area Z2 (according to the example of FIGS. 6 and 7).

Nevertheless, the methods described previously in relation to FIG. 4 and in relation to FIGS. 6 and 7 can be combined, in order both to increase the rate of etching the dielectric spacer material SP in the first area Z1 and to decrease the rate of etching the dielectric spacer material SP in the second area Z2. In this case, the same temporary mask MSK_RES could be used not only to define the hard mask MSK_OX (FIG. 7), but also to define the implantation IMP (FIG. 4). Alternatively, combining the two treatment examples, with two different provisional mask photolithography steps, could be used to define three areas resulting in three different thicknesses of dielectric spacer material, and therefore dielectric regions of sidewall spacers that may have three different widths on the sides of gate stacks of the same category. Indeed, one could prepare in this regard a first area the etching rate of which is increased, a second area the etching rate of which is unchanged and a third area the etching rate of which is reduced.

FIG. 9 illustrates an integrated circuit CI which may have been obtained by the method described in relation to FIGS. 1 to 8, including MOS transistors having gate stacks belonging to several examples of gate stacks categories LV, IO, HV, FG.

At least a first low voltage transistor LVT1 and at least a second low voltage transistor LVT2 have gate stacks belonging to a low voltage gate stack category LV, and are intended to operate at gate voltages less than 2 volts.

The low voltage gate stacks LV include, for example, a first type of gate oxide GOX1, and a second type of conductive gate region G2.

Said at least a first low voltage transistor LVT1 includes dielectric regions of sidewall spacers SP11 having a first width L11, and said at least a second low voltage transistor LVT2 includes dielectric regions of sidewall spacers SP12 having a second width L12 different from the first width L11.

At least a first medium voltage transistor IOT1 and at least a second medium voltage transistor IOT2 have gate stacks belonging to a category of medium voltage gate stacks IO, and are intended to operate at gate voltages comprised between 1.5 volts and 5 volts.

The medium voltage gate stacks IO include, for example, a second type of gate oxide GOX2, and the second type of conductive gate region G2.

Said at least a first medium voltage transistor IOT1 includes dielectric regions of sidewall spacers SP21 having a first width L21, and said at least a second medium voltage transistor IOT2 includes dielectric regions of sidewall spacers SP22 having a second width L22 different from the first width L21.

For example, the dielectric regions of sidewall spacers SP11, SP12, SP21, SP22 of the low voltage transistors LVT1, LVT2 and the medium voltage transistors IOT1, IOT2 may have been formed simultaneously by a common implementation of the method described previously in relation to FIGS. 1 to 8. In which case, the first widths L11 and L21 are substantially equal, and the second widths L12 and L22 are substantially equal.

At least a first high voltage transistor HVT1 and at least a second high voltage transistor HVT2 have gate stacks belonging to a category of high voltage gate stacks HV, and are intended to operate at gate voltages comprised between 5 volts and 15 volts.

The high voltage gate stacks HV include, for example, a third type of gate oxide GOX3, and a first type of conductive gate region G1.

Said at least a first high voltage transistor HVT1 includes dielectric regions of sidewall spacers SP31 having a first width L31, and said at least a second high voltage transistor HVT2 includes dielectric regions of sidewall spacers SP32 having a second width L32 different from the first width L31.

At least a first floating gate transistor FGT1 and at least a second floating gate transistor FGT2 have gate stacks belonging to a category of memory cell gate stacks FG including a superposition of a control gate stack RGC on a floating gate stack RGF.

The floating gate stacks RGF include for example a fourth type of gate oxide GOX4, and the first type of conductive gate region G1, and the control gate stacks RGC include for example a type of inter-gate oxide GOX12, and the second type of conductive gate region G2.

Said at least a first floating gate transistor FGT1 includes dielectric regions of sidewall spacers SP41 having a first width L41, and said at least a second floating gate transistor FGT2 has dielectric regions of sidewall spacers SP42 having a second width L42 different from the first width L41.

For example, the dielectric regions of sidewall spacers SP31, SP32, SP41, SP42 of the high voltage transistors HVT1, HVT2 and the floating gate transistors FGT1, FGT2 may have been formed simultaneously by a common implementation of the method described previously in relation to FIGS. 1 to 8. In which case, the first widths L31 and L41 are substantially equal, and the second widths L32 and L42 are substantially equal.

Finally, it will be noted that the source S and drain D regions of each first transistor LVT1, IOT1, HVT1, FGT1 are closer to each other than the source S and drain D regions of respectively each second transistor LVT2, IOT2, HVT2, FGT2.

It will be recalled that the conduction regions thus represented (S, D), which have been implanted in self-alignment on the outer edges of the dielectric regions of sidewall spacers SP11-SP42 can be regions called “low doped drain” regions which do not, in themselves, constitute the source S and drain D regions. Another implantation step could be implemented in a conventional manner to form the final source and drain regions of the transistors.

In any case, among transistors having gate stacks belonging to the same category LV, IO, HV, FG, it was possible to modulate the length of the channel region, between the two conduction regions S, D. Thus, it has been possible to optimize or improve the performance of the transistors, in particular the residual current in the turned-off state (usually “Ioff”), the saturation drain current (usually “IDsat”), the resistance in the turned-on state (usually “Ron”); the reliability of transistors, in particular ageing and the phenomena of degradation by hot carriers; and also the size of the transistors.

1. A method for manufacturing transistors of the metal-oxide-semiconductor “MOS” type on a semiconductor substrate of an integrated circuit, comprising:
manufacturing gate stacks of at least one gate stack category;
forming a conformal layer of a dielectric spacer material on the gate stacks of said at least one gate stack category;
isotropic etching to selectively reduce, without completely removing, a thickness of the dielectric spacer material in a first area opposite at least a first gate stack of said at least one gate stack category, and not in a second area opposite at least a second gate stack of said gate stack category; and
anisotropic etching to completely remove the thickness of the dielectric spacer material on top of said gate stacks and on top of the substrate and leave a remainder of the thickness of dielectric spacer material laterally on sides of said first and second gate stacks of said at least one gate stack category in the first area and in the second area, respectively.

2. The method according to claim 1, wherein manufacturing gate stacks for each gate stack category comprises performing a set of common steps including forming a dielectric gate layer on the semiconductor substrate and forming a conductive gate layer on the dielectric gate layer.

3. The method according to claim 1, further comprising forming conduction regions for the transistors comprising implanting dopants in the semiconductor substrate self-aligned on an outer edge of the remainders of the thickness of dielectric spacer material on the sides of the gate stacks of said at least one gate stack category.

4. The method according to claim 1, wherein isotropic etching comprises performing a wet etch with a chemical species adapted for etching the dielectric spacer material.

5. The method according to claim 1, further comprising, prior to performing the isotropic etching, treating the dielectric spacer material to selectively modify a reaction rate of the dielectric spacer material with an etchant of said isotropic etching in at least one of the first area or the second area, so that the reaction rate of the dielectric spacer material with the etchant is greater in the first area than in the second area.

6. The method according to claim 5, wherein treating comprises using a temporary mask which uncovers the first area and covers the second area, and performing an ion implantation adapted to damage the dielectric spacer material in the first area so as to increase the reaction rate of the dielectric spacer material in the first area.

7. The method according to claim 6, wherein an energy of the implantation is configured according to the choice of the ionic species, and according to the thickness of the dielectric spacer material and the desired reduction of said thickness during the isotropic etching step.

8. The method according to claim 5, wherein treating comprises using a hard mask which uncovers the first area and covers the second area, a material of the hard mask being adapted to withstand said etchant so as to at least one of reduce the reaction rate or prevent the reaction of the dielectric spacer material in the second area.

9. The method according to claim 8, further comprising, after isotropic etching, selectively removing the hard mask without degrading the dielectric spacer material.

10. The method according to claim 1, wherein said at least one gate stack category comprises a category of low voltage gate stacks intended to operate at gate voltages less than 2 volts.

11. The method according to claim 1, wherein said at least one gate stack category comprises a category of medium voltage gate stacks intended to operate at gate voltages comprised between 1.5 volts and 5 volts.

12. The method according to claim 1, wherein said at least one gate stack category comprises a category of high voltage gate stacks intended to operate at gate voltages comprised between 5 volts and 15 volts.

13. The method according to claim 1, wherein said at least one gate stack category comprises a category of memory cell gate stacks including a superposition of a control gate stack on a floating gate stack.

14. A method for manufacturing transistors of the metal-oxide-semiconductor “MOS” type on a semiconductor substrate of an integrated circuit, comprising:
manufacturing a plurality of gate stacks;
forming a conformal layer of a dielectric spacer material on the gate stacks;
applying a mask which uncovers a first area opposite at least a first gate stack of said plurality of gate stacks and covers a second area opposite at least a second gate stack of said plurality of gate stacks;
using said mask, selectively treating the dielectric spacer material in the first area to modify an etching reaction rate of the dielectric spacer material to be greater in the first area than in the second area;
removing the mask;
performing an isotropic etching to selectively reduce, without completely removing, a thickness of the dielectric spacer material in said first area and not in a second area opposite;
performing an anisotropic etching to completely remove the thickness of the dielectric spacer material on top of said gate stacks and on top of the substrate and leave a remainder of the thickness of dielectric spacer material laterally on sides of said first and second gate stacks in the first area and in the second area, respectively.

15. The method according to claim 14, further comprising forming conduction regions for the transistors comprising implanting dopants in the semiconductor substrate self-aligned on an outer edge of the remainders of the thickness of dielectric spacer material on the sides of the first and second gate stacks.

16. The method according to claim 14, wherein selectively treating comprises performing an ion implantation using said mask that damages the dielectric spacer material in the first area so as to increase the reaction rate of the dielectric spacer material in the first area.

17. An integrated circuit, comprising:
metal-oxide-semiconductor “MOS” type transistors disposed on a semiconductor substrate;
said MOS type transistors having gate stacks belonging to at least one gate stack category and dielectric regions of sidewall spacers on the sides of the gate stacks;
wherein at least a first transistor of said MOS type transistors has a gate stack of said at least one gate stack category that includes dielectric regions of sidewall spacers having a first width; and
wherein at least a second transistor of said MOS type transistors has a gate stack of said at least one gate stack category that includes dielectric regions of sidewall spacers having a second width different from the first width.

18. The integrated circuit according to claim 17, wherein each gate stack comprises a dielectric gate layer on the semiconductor substrate and a conductive gate layer on the dielectric gate layer, and wherein the gate stacks belonging to a same gate stack category include structurally identical dielectric gate layers and structurally identical conductive gate layers.

19. The integrated circuit according to claim 17, wherein the MOS type transistors comprise conduction regions aligned on an outer edge of a width of the dielectric regions of sidewall spacers.

20. The integrated circuit according to claim 17, wherein said at least one gate stack category comprises a category of low voltage gate stacks intended to operate at gate voltages less than 2 volts.

21. The integrated circuit according to claim 17, wherein said at least one gate stack category comprises a category of medium voltage gate stacks intended to operate at gate voltages comprised between 1.5 volts and 5 volts.

22. The integrated circuit according to claim 17, wherein said at least one gate stack category comprises a category of high voltage gate stacks intended to operate at gate voltages comprised between 5 volts and 15 volts.

23. The integrated circuit according to claim 17, wherein said at least one gate stack category comprises a category of memory cell gate stacks including a superposition of a control gate stack on a floating gate stack.
